(19) United States
(12) Patent Application Publication
(10) Pub. No.: US 2007/0138638 A1
(43) Pub. Date: Jun. 21, 2007

(54) Semiconductor device

(75) Inventors: Yukitoshi Ota, Osaka (JP); Noriyuki Nagai, Nara (JP); Tsuyoshi Hamatani, Shiga (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Osaka (JP)

(21) Appl. No.: 11/594,875

(22) Filed: Nov. 9, 2006

(30) Foreign Application Priority Data
Dec. 21, 2005 (JP) 2005-367293

(51) Int. Cl. H01L 23/52

(52) U.S. Cl. 257/758

(57) ABSTRACT

In a semiconductor device having a multilayer interconnection structure, wires are formed by a damascene process, at least part of electrode pads includes a first conductive layer having a region provided for an electrical connection with an external unit. Herein, the first conductive layer is formed on a passivation film that is formed a semiconductor substrate and is indispensable for the multilayer interconnection structure.

### BACKGROUND OF THE INVENTION

(1) Field of the Invention

The present invention relates to a semiconductor device of a multilayer interconnection structure having a plurality of interlayer insulating films, a plurality of wires and a plurality of electrode pads respectively formed on a semiconductor substrate.

(2) Description of the Related Art

There is an increasing demand for a high-performance and multifunctional semiconductor device with the recent advancement of digitalization. In order to satisfy this demand, electrode pads in a semiconductor device are increased in number. On the other hand, in order to achieve size reduction and cost reduction for an electronic apparatus, a semiconductor chip must be further reduced in size. Solutions of these problems include multilayer interconnection and microfabrication of wires. However, it is effective to utilize a region below an electrode pad.

In order to effectively utilize a region below an electrode pad, an area pad structure that a semiconductor element is formed below an electrode pad is adopted as an example that a region below an electrode pad is utilized as, for example, an electronic circuit formation region.

In the case where such area pad structure is adopted, it is important to prevent cracking from occurring at a region below an electrode pad when a probe or the like gives an impact to the electrode pad upon performance of an electrical test for a semiconductor device, and to suppress an increase in manufacturing steps required for adopting the area pad structure.

The former consideration is important because of the following reason. That is, if cracking occurs at the region below the electrode pad, a semiconductor element formed at the region below the electrode pad is damaged and electrical leakage between the electrode pad and a wire formed at the region below the electrode pad occurs. Consequently, there is a possibility that the semiconductor device may lose its functionality. On the other hand, the later consideration is important because of the following reason. That is, the increase in the manufacturing steps disadvantageously leads to addition of cost.

Herein, with reference to FIG. 5, description will be given of a conventional area pad structure for preventing cracking from occurring at a region below an electrode pad when the electrode pad receives an impact in an electrical test such as a probe test or a WLBI (Wafer Level Burn-In) test for a semiconductor device and for suppressing an increase in manufacturing steps required for adopting the area pad structure (refer to, for example, JP2004-14609A).

FIG. 5 is a sectional view illustrating a structure of an electrode pad in a conventional semiconductor device. As illustrated in FIG. 5, the semiconductor device comprises a semiconductor substrate 1, insulating films 2 and 3, a passivation film 4, an electrode pad including a conductive layer (a first conductive layer) 5 having a region provided for a connection with an external unit, and a semiconductor element 6. The insulating film 2 includes a via 22 provided for a contact with the semiconductor element 6. The insulating film 3 includes wires 31a, 31b, 31c and 31d, and a via 32.

As illustrated in FIG. 5, the semiconductor device has the following configuration. That is, in the insulating film 3, the wires 31a and 31b are separated from each other with a portion 33a interposed therebetween, the wires 31b and 31c are separated from each other with a portion 33b interposed therebetween, and the wires 31c and 31d are separated from each other with a portion 33c interposed therebetween. Therefore, each of the wires 31a, 31b and 31c can be used as a wire isolated from the first conductive layer 5 except the wire 31d connected to the first conductive layer 5 through the via 32.

Even when the first conductive layer 5 in this area pad structure receives an impact upon performance of an electrical test such as a probe test or a WLBI test, each of the portions 33a, 33b and 33c in the insulating film 3 serves as a support strut for relieving the impact. Thus, it is possible to prevent cracking from occurring at the insulating film 3 and the insulating film 2 formed below the insulating film 3.

A material and conditions for manufacturing the semiconductor device adopting this area pad structure are equal to those typically utilized upon manufacturing of a conventional semiconductor device. Further, it is unnecessary to add a new layer such as a polyimide film as an insulating film. This leads to suppression of additional cost due to an increase in manufacturing steps.

In the area pad structure of the conventional semiconductor device, an insulating film serving as a support strut between uppermost wires is integrated with an insulating film on each wire. If the uppermost wire is an Al wire formed by sputtering, this integral structure can be formed without problems even when the uppermost wire is used as a wire isolated from a first conductive film. However, if the uppermost wire is a Cu wire formed only by a damascene process, the Cu wire is formed in such a manner that a groove for the wire is formed in the insulating film and, then, a wire material made of Cu is embedded into the groove. Consequently, the insulating film serving as a support strut between wires is not integrated with the insulating film on each wire.

In order to use an uppermost wire as a wire isolated from a first conductive layer like the aforementioned area pad structure in the case where the Al wire is formed by sputtering, an additional insulating film must be formed between the uppermost wire and the first conductive layer. If the insulating film is additionally formed, manufacturing steps are disadvantageously increased in number. This leads to addition of cost.

### SUMMARY OF THE INVENTION

The present invention is made to solve the aforementioned problems. An object of the present invention is to provide a semiconductor device. With this semiconductor device, in the case where a wire is formed below an electrode pad on a multilayer substrate by a damascene process, it is possible to suppress an increase in manufacturing steps which causes addition of cost, and to effectively utilize a region below the electrode pad.

In order to accomplish this object, the present invention provides a semiconductor device having a multilayer interconnection structure, comprising a semiconductor substrate, a plurality of interlayer insulating films, a plurality of wires each formed by a damascene process, and a plurality of electrode pads each provided for an electrical connection with an external unit, the respective interlayer insulating films, wires, and electrode pads being provided on the semiconductor substrate. Herein, at least part of the electrode pads has a first conductive layer that is formed on a passivation film on the semiconductor substrate and has a region provided for the electrical connection with the external unit, and a second conductive layer that is formed immediately below the passivation film and has the plurality of wires. At least part of the wires in the second conductive layer vertically overlaps with the first conductive layer on the semiconductor substrate while establishing no electrical connection with the first conductive layer.

According to a first aspect of the present invention, in the case where a semiconductor device has a multilayer interconnection structure wherein wires are formed by a damascene process, a first conductive layer of an electrode pad is formed on a passivation film that is formed on a semiconductor substrate and is indispensable for the multilayer interconnection structure. Accordingly, the first conductive layer is not directly and electrically connected to wires in a second conductive layer, respectively, without an increase in manufacturing steps.

Therefore, a region corresponding to the second conductive layer can be used freely. In other words, a region below the electrode pad can be utilized effectively.

According to a second aspect of the present invention, in the case where a semiconductor device has a multilayer interconnection structure wherein wires are formed by a damascene process, a wire in a second conductive layer is formed at a portion vertically overlapping with a testing region of a first conductive layer. Thus, the first conductive layer is not directly and electrically connected to wires in the second conductive layer vertically overlapping with a region other than the testing region, respectively.

Therefore, in the second conductive layer, the region vertically overlapping with the region other than the testing region of the first conductive layer can be used freely. In other words, the region below the electrode pad can be utilized effectively. Thus, occurrence of cracking at a passivation film can be suppressed.

According to a third aspect of the present invention, a semiconductor device has a multilayer interconnection structure wherein wires are formed by a damascene process. In a second conductive layer, a wire vertically overlapping with a testing region of a first conductive layer is directly and electrically connected to the first conductive layer. Therefore, even in the case where cracking occurs at a passivation film in a testing step such as a probe test or a WLBI test and electrical leakage occurs between the first conductive layer and the wire in the second conductive layer, the semiconductor device can be operatively allowed to function as a circuit without problems.

Hence, in the second conductive layer, a region vertically overlapping with a region other than the testing region of the first conductive layer can be used freely. In other words, a region below an electrode pad can be utilized effectively. Even when cracking occurs at the passivation film, a test such as a probe test or a WLBI test can be performed normally.

According to a fourth aspect of the present invention, a semiconductor device has a multilayer interconnection structure wherein wires are formed by a damascene process. Herein, a passivation film has an opening formed at a portion vertically overlapping with a testing region of a first conductive layer. Therefore, the passivation film can be eliminated at a point receiving an impact in a testing step such as a probe test or a WLBI test.

Hence, in a second conductive layer, a region vertically overlapping with a region other than the testing region of the first conductive layer can be used freely. In other words, a region below an electrode pad can be utilized effectively. Further, there is no occurrence of cracking at the passivation film. Therefore, there arise no problems due to cracking at the passivation film, such as separation of the electrode pad at a crack.

### BRIEF DESCRIPTION OF THE DRAWINGS

FIG. 1A is a plan view illustrating a structure of a semiconductor device according to a first embodiment of the present invention;

FIG. 1B is a sectional view illustrating the structure of the semiconductor device according to the first embodiment of the present invention;

FIG. 2A is a plan view illustrating a structure of a semiconductor device according to a second embodiment of the present invention;

FIG. 2B is a sectional view illustrating the structure of the semiconductor device according to the second embodiment of the present invention;

FIG. 3A is a plan view illustrating a structure of a semiconductor device according to a third embodiment of the present invention;

FIG. 3B is a sectional view illustrating the structure of the semiconductor device according to the third embodiment of the present invention;

FIG. 4A is a plan view illustrating a structure of a semiconductor device according to a fourth embodiment of the present invention;

FIG. 4B is a sectional view illustrating the structure of the semiconductor device according to the fourth embodiment of the present invention; and

FIG. 5 is a sectional view illustrating a structure of an electrode pad in a conventional semiconductor device.

### DESCRIPTION OF THE PREFERRED EMBODIMENTS

Hereinafter, detailed description will be given of a semiconductor device according to the present invention with reference to the drawings.

In each of preferred embodiments of the present invention, as an example, a semiconductor device includes two insulating films and Cu wires and is formed by a dual damascene process. Manufacturing steps and manufacturing conditions for the semiconductor device according to the present invention are basically equal to those for a typical semiconductor device; therefore, specific description thereof will not be given here.

### First Embodiment

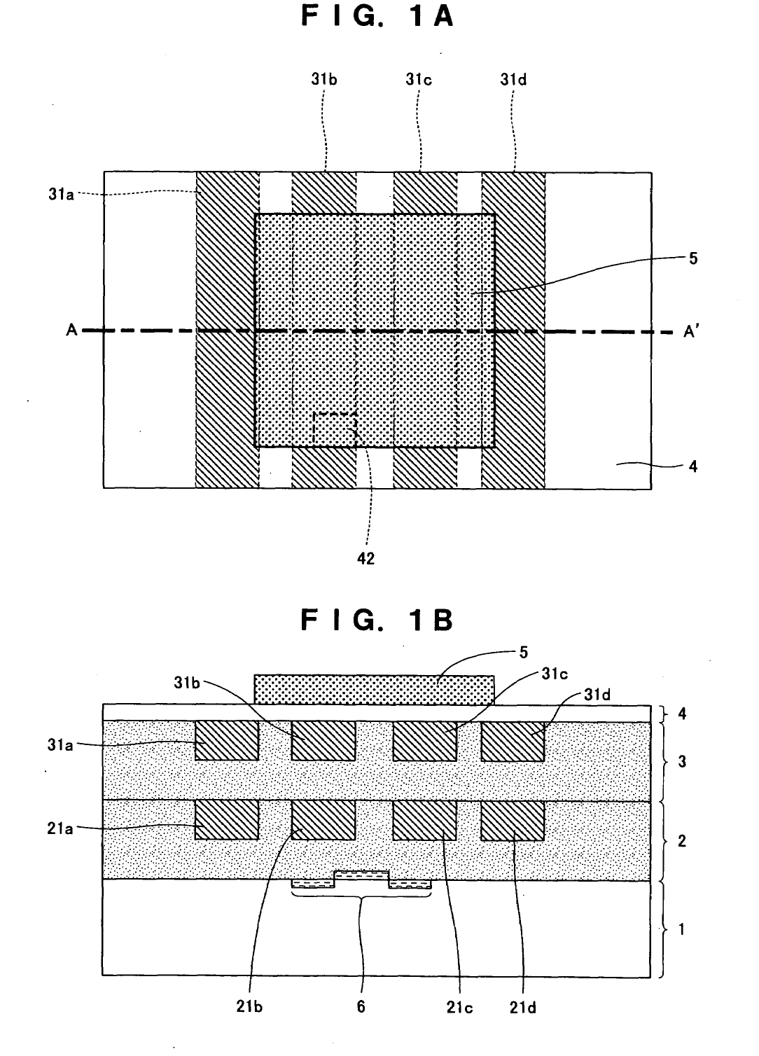

With reference to FIGS. 1A and 1B, description will be given of a structure of a semiconductor device according to a first embodiment of the present invention.

FIG. 1A is a plan view illustrating the structure of the semiconductor device according to the first embodiment. FIG. 1B is a sectional view taken along a line A-A′ in FIG. 1A, and schematically illustrates the structure of the semiconductor device according to the first embodiment.

As illustrated in FIGS. 1A and 1B, insulating films 2 and 3 each made of, for example, a dielectric oxide and a passivation film 4 made of, for example, a silicon nitride are formed on a semiconductor substrate 1. In the semiconductor device, wires 31a, 31b, 31c and 31d are formed in a second conductive layer of the insulating film 3 below a first conductive layer 5 of an electrode pad, wires 21a, 21b, 21c and 21d are formed in the insulating film 2, and a semiconductor element 6 is formed on the semiconductor substrate 1.

The first conductive layer 5 is formed on the passivation film 4 and is connected to the wire 31b in the second conductive layer through an opening 42 formed in the passivation film 4.

A barrier film made of, for example, TaN is formed between the insulating film 2 and the insulating film 3. Further, a barrier film made of, for example, TaN is formed between a via and a wire in each of the insulating films 2 and 3. In addition, a barrier film made of, for example, Ti and TiN is formed between the passivation film 4 and the first conductive layer 5.

Next, description will be given of a manufacturing method of the semiconductor device according to the first embodiment.

The manufacturing method of the semiconductor device according to the first embodiment is equal to that of a typical semiconductor device. That is, in the case where wires and a via are made of Cu, respectively, an insulating film 2 made of a dielectric oxide is formed by CVD (Chemical Vapor Deposition) on a semiconductor substrate 1 having a semiconductor element 6 formed thereon.

Next, a via hole and wire grooves are formed in the insulating film 2 by photolithography and etching. Then, a barrier metal (for example, TaN) film and a Cu seed film are formed by, for example, sputtering. Thereafter, a Cu film is deposited on the Cu seed film by electrolytic plating, thereby to form a via and wires 21a, 21b, 21c and 21d.

Next, the Cu film is removed so as to bare a top face of the insulating film 2 by, for example, CMP (Chemical Mechanical Planarization). The aforementioned processes are performed repeatedly to form an insulating film 3, and a via and wires 31a, 31b, 31c and 31d in a second conductive layer of the insulating film 3.

Next, a passivation film 4 made of a silicon nitride is formed by, for example, CVD, and an opening 42 is formed in the passivation film 4 by photolithography and etching. Then, a barrier film made of Ti and TiN is formed by sputtering, and a first conductive layer 5 made of, for example, Al is formed by photolithography and etching.

As described above, the first embodiment provides the following structure. That is, in the semiconductor device having a multilayer interconnection structure that wires are formed by a damascene process, at least part of the electrode pad illustrated in FIGS. 1A and 1B includes the first conductive layer 5 that has a region provided for an electrical connection with an external unit and is formed on the passivation film 4.

The passivation film 4 is provided for protecting a semiconductor element from a mechanical stress and impurities, and is indispensable in the case where a wire readily undergoing oxidation, such as a Cu wire formed by a damascene process, is formed as an uppermost wire. The first conductive layer 5 of the electrode pad is formed on the indispensable passivation film 4. Thus, the first conductive layer 5 is not directly and electrically connected to each of the wires 31a, 31b, 31c and 31d in the second conductive layer without an increase in manufacturing steps, and a region below the electrode pad can be utilized effectively.

### Second Embodiment

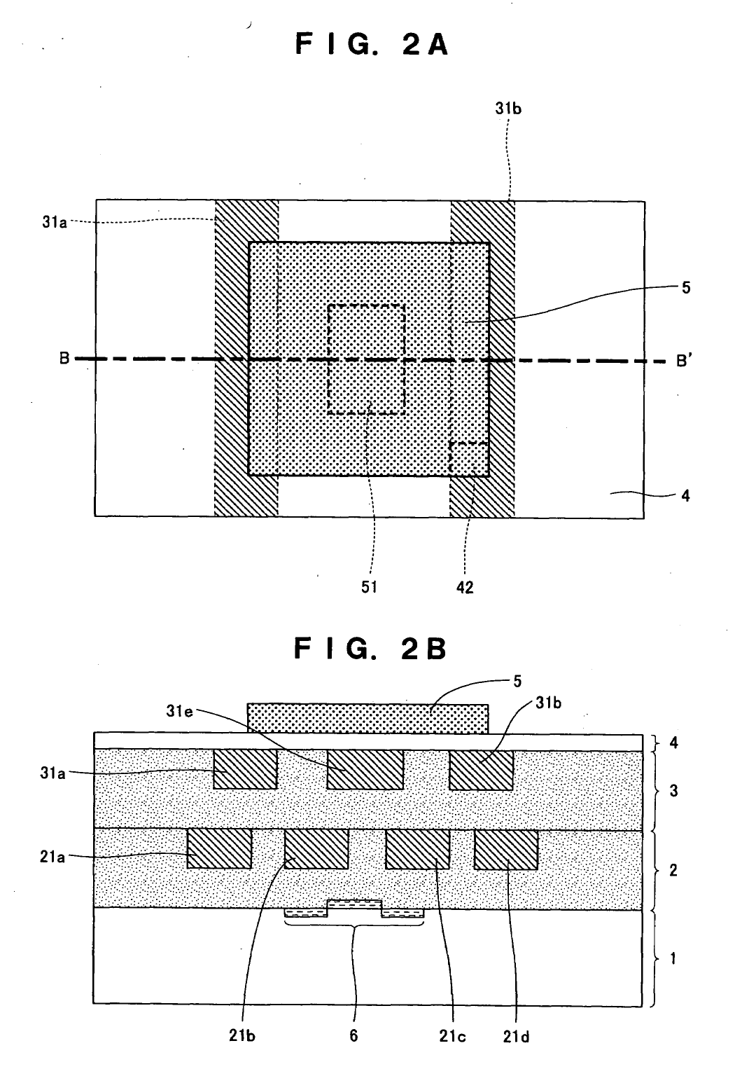

With reference to FIGS. 2A and 2B, description will be given of a structure of a semiconductor device according to a second embodiment of the present invention.

FIG. 2A is a plan view illustrating the structure of the semiconductor device according to the second embodiment. FIG. 2B is a sectional view taken along a line B-B′ in FIG. 2A, and schematically illustrates the structure of the semiconductor device according to the second embodiment.

Herein, description will be given of only a difference between the first embodiment and the second embodiment.

FIG. 2A illustrates a testing region 51 receiving an impact by a contact with a probe in a probe test or a bump in a WLBI test. A point that the probe or the bump comes into contact with a first conductive layer 5 of an electrode pad differs for each testing even in one electrode pad of one chip in a wafer. This contact point has variations in a range from several micrometers to several tens of micrometers depending on a probe of a probing apparatus, a bump of a WLBI apparatus, or an alignment deviation of a wafer.

Accordingly, the testing region 51 includes not only a point that an impact is actually given to a first conductive layer 5 of each electrode pad but also a point having a possibility that an impact in consideration of the variations is given. A wire 31e in a second conductive layer is formed as a dummy wire in an insulating film 3 formed below the testing region 51.

In FIGS. 2A and 2B, the wire 31e in the second conductive layer is formed as a dummy wire and is equal in size to the testing region 51. However, the wire 31e may be larger than the testing region 51 as long as the dummy wire contains a portion below the testing region 51. In the wire 31e, a portion other than a portion overlapping with the testing region 51 may be used as a normal wire. Moreover, a manufacturing method of the semiconductor device according to the second embodiment is similar to that of the semiconductor device according to the first embodiment.

As described above, the second embodiment provides the following structure. That is, in the second conductive layer of the insulating film 3, the wire 31e is formed as a dummy wire at a portion vertically overlapping with the testing region 51 of the first conductive layer 5.

On the other hand, in manufacturing steps including a semiconductor device assembling step, examples of a step in which an electrode pad receives an impact include a probe testing step, a WLBI testing step and a wire bonding step. Herein, an impact to be given to an electrode pad is small in the wire bonding step as compared with the probe testing step and the WLBI testing step.

This fact is demonstrated by experiment. Upon performance of wire bonding in which a ball width is about 80 μm, in the area pad structure in the first embodiment, no cracking occurs at the passivation film 4 formed below the first conductive layer 5. However, upon performance of a cantilever probe test under normal conditions in which an overdrive amount is about 60 μm or a WLBI test in which a load is 10 gf for each normal bump, cracking occurs at the passivation film 4.

A wire formed at a lower layer receiving an impact in an insulating film is softer than the insulating film and, therefore, is readily deformed. This deformation enables to absorb the impact to an upper layer in the insulating film. However, if both a portion corresponding to the soft wire and a portion corresponding to the hard insulating film are present at the lower layer receiving the impact, only the portion corresponding to the soft wire is deformed, so that stress concentration occurs at an interface between the insulating film and the wire at the lower layer. Consequently, cracking readily occurs at the upper layer of the insulating film.

In order to prevent this disadvantage, in the second conductive layer of the insulating film 3, the wire 31e is formed as a dummy wire at the portion vertically overlapping with the testing region 51 of the first conductive layer 5, so that occurrence of cracking can be suppressed at the passivation film 4. Further, a portion vertically overlapping with the first conductive layer 5 other than the testing region 51, that is, wires 31a and 31b in the second conductive layer can be used freely. In other words, the wires formed in the second conductive layer of the insulating film 3 can be utilized effectively.

### Third Embodiment

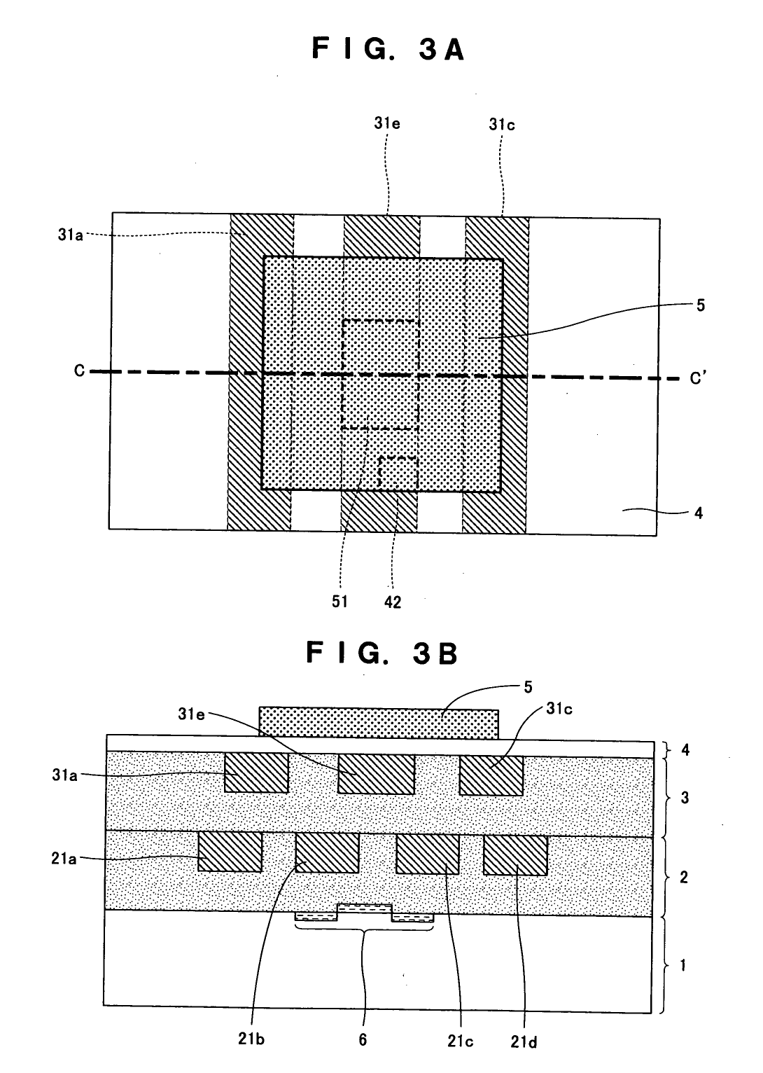

With reference to FIGS. 3A and 3B, description will be given of a structure of a semiconductor device according to a third embodiment of the present invention.

FIG. 3A is a plan view illustrating the structure of the semiconductor device according to the third embodiment. FIG. 3B is a sectional view taken along a line C-C′ in FIG. 3A, and schematically illustrates the structure of the semiconductor device according to the third embodiment.

Herein, description will be given of only a difference between the second embodiment and the third embodiment.

As illustrated in FIG. 3A, in an insulating film 3, a wire 31e in a second conductive layer formed below a testing region 51 of a first conductive layer 5 is electrically connected to the first conductive layer 5 through an opening 42 formed in a passivation film 4. A manufacturing method of the semiconductor device according to the third embodiment is similar to that of the semiconductor device according to the first embodiment.

As described above, the third embodiment provides the following structure. That is, in the second conductive layer of the insulating film 3, the wire 31e vertically overlapping with the testing region 51 of the first conductive layer 5 is directly and electrically connected to the first conductive layer 5. Therefore, even in the case where cracking occurs at the passivation film 4 in a testing step such as a probe test or a WLBI test and electrical leakage occurs between the first conductive layer 5 and the wire 31e in the second conductive layer, the wire 31e is electrically connected to the first conductive layer 5; therefore, there arise no functional problems about the semiconductor device as a circuit.

Hence, a probe test or a WLBI test can be performed even under a condition that cracking occurs at the passivation film 4.

### Fourth Embodiment

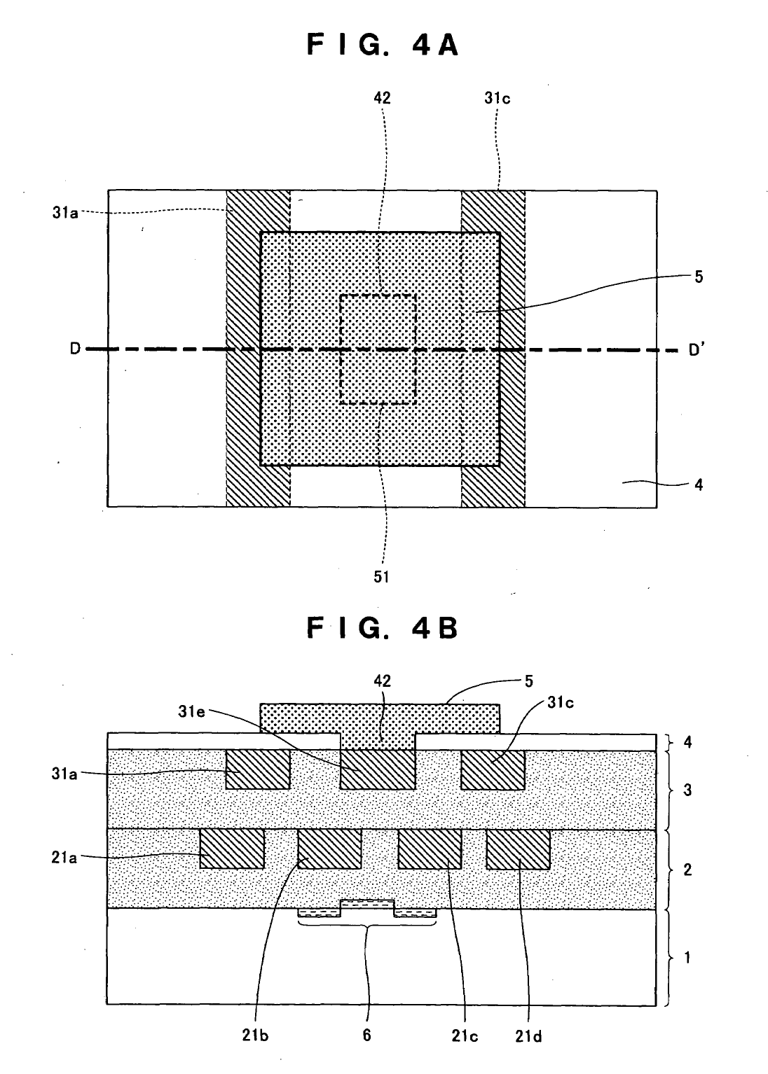

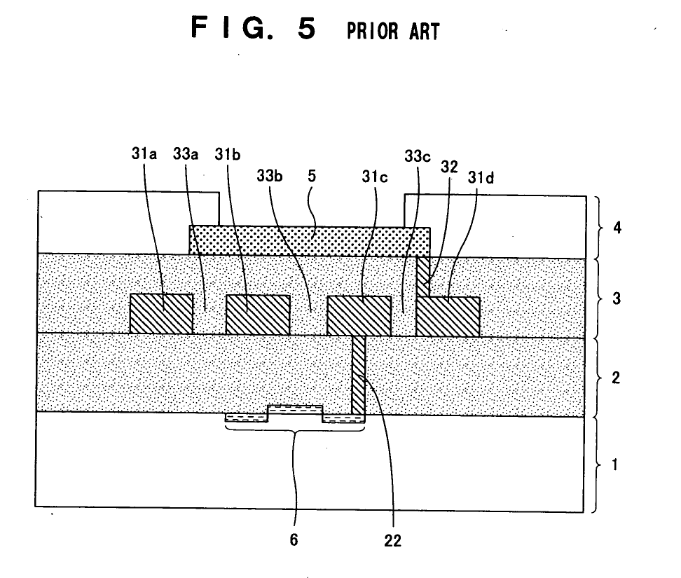

With reference to FIGS. 4A and 4B, description will be given of a structure of a semiconductor device according to a fourth embodiment of the present invention.

FIG. 4A is a plan view illustrating the structure of the semiconductor device according to the fourth embodiment. FIG. 4B is a sectional view taken along a line D-D′ in FIG. 4A, and schematically illustrates the structure of the semiconductor device according to the fourth embodiment.

Herein, description will be given of only a difference between the third embodiment and the fourth embodiment.

As illustrated in FIG. 4A, an opening 42 is formed in a passivation film 4 formed below a testing region 51 of a first conductive layer 5 so as to have a size equal to that of the testing region 51. A wire 31e in a second conductive layer of an insulating film 3 is connected to the first conductive layer 5 through the opening 42 in the passivation film 4. A manufacturing method of the semiconductor device according to the fourth embodiment is similar to that of the semiconductor device according to the first embodiment.

As described above, the fourth embodiment provide the following structure. That is, in the passivation film 4, the opening 42 is formed at a portion vertically overlapping with the testing region 51 of the first conductive layer 5. Therefore, at a point receiving a mechanical impact in a testing step such as a probe test or a WLBI test, the passivation film 4 can be eliminated.

Accordingly, cracking occurring at the passivation film 4 does not extend to the opening 42 in the passivation film 4. Thus, there arise no mechanical and electrical problems caused by occurrence of cracking at the passivation film 4, such as separation of an electrode pad at a crack.

What is claimed is:

1. A semiconductor device having a multilayer interconnection, comprising:
a semiconductor substrate,
a plurality of interlayer insulating films,
a plurality of wires each formed by a damascene process, and
a plurality of electrode pads each provided for electrical connection with an external unit,
the interlayer insulating films, wires, and electrode pads being provided on the semiconductor substrate, wherein
at least part of the electrode pads has a first conductive layer formed on a passivation film over the semiconductor substrate and having a region for the electrical connection with the external unit,
a second conductive layer having the plurality of wires is formed immediately below the passivation film, and
at least part of the wires in the second conductive layer vertically overlaps with the first conductive layer formed on the semiconductor substrate while establishing no electrical connection with the first conductive layer.

2. The semiconductor device according to claim 1, wherein the wire in the second conductive layer, which vertically overlaps with the first conductive layer formed on the semiconductor substrate, vertically overlaps at least with a testing region of the first conductive layer.

3. The semiconductor device according to claim 2, wherein the wire in the second conductive layer, which vertically overlaps with the testing region of the first conductive layer, is directly and electrically connected to the first conductive layer.

4. The semiconductor device according to claim 3, wherein the passivation film has an opening formed at a portion vertically overlapping with the testing region of the first conductive layer, and the first conductive layer is electrically connected to the wire in the second conductive layer through the opening in the passivation film.
